(19) United States
(12) Patent Application Publication
(10) Pub. No.: US 2016/0294079 A1
(43) Pub. Date: Oct. 6, 2016

(54) Electric Connector

(71) Applicant: SUMIDA flexible connections GmbH, Radeberg (DE)

(72) Inventor: Patrick Heine, Kamenz (DE)

(73) Assignee: SUMIDA flexible connections GmbH, Radeberg (DE)

(21) Appl. No.: 15/060,752

(22) Filed: Mar. 4, 2016

(30) Foreign Application Priority Data
Mar. 31, 2015 (DE) 10 2015 104 923.6

(51) Int. Cl. H01R 12/62; H05K 1/14

(52) U.S. Cl. CPC H01R 12/62; H05K 1/14; H05K 2201/04

(57) ABSTRACT

An electric connector that is particularly suitable for connecting printed circuit boards, wherein the connector has several flat conductors that are spaced apart from each other and that are embedded in an electrically insulating material to form an insulation zone in which the flat conductors extend parallel to each other and at their ends each with an exposed portion project over the transverse edges of the insulation zone. Here, it is provided that each of the flat conductors, within the insulation zone, has at least one first portion that is arranged between two second portions, wherein the first portion has a smaller thickness than the second portions.

The invention relates to an electric connector that is particularly suitable for electrically connecting printed circuit boards as well as electric and electronic components.

For connecting two printed circuit boards electric connectors are required that can allow the current flow between the conductor paths of one printed circuit board and the conductor paths of the other printed circuit board. Such an electric connector is known from DE 10 2005 056 147 A1 of Sumida flexible connections GmbH that can also be used as SMD connector (SMD: surface-mounted device) for surface mounting (surface-mounted technology, SMT). According to FIG. 1 there the electric connector comprises a flat cable at the insulation-free ends of which z-shaped conductor ends are formed. The outer leg of the z-shaped conductor ends is brought into contact with the conductor path of a printed circuit board.

Electric connectors may be exposed to high mechanical stresses. This is particularly the case when the terminals of the two electric or electronic components to be connected with the electric connector are not in one plane. Then, the electric connector has to be bent. Especially, in small space only allowing the use of electric connectors having a short insulation zone the conductors are exposed to considerable bending stresses within the insulation zone. Thus, for connecting electric or electronic components conventional electric connectors are only suitable under certain circumstances. If the conductors are bent too much or too often within the insulation zone, so the conductors can break or crack what can significantly affect their electric properties.

At the first glance, this problem could be solved by providing electric connectors that are specifically adapted to the spatial arrangement of the components for the connection of which they should be used. However, this would require the production of various different modifications of electric connectors. Thus, a change in the spatial arrangement of the components would require the development and use of other electric connectors.

The problem would be left completely unresolved if the connected components functionally change their spatial position to each other repeatedly. For example, this is the case if one of the components is movably arranged relative to the other component. Also conceivable would be the use of flat conductors, e.g. film-type flat conductors, which are as thin as they hardly offer mechanical resistance to bending. However, such films neither have the required electric properties nor are the exposed areas of such films suitable for SMD mounting.

DE 38 42 572 A1 of Robert Bosch GmbH describes a method for the manufacture of an electric connector to be used for electrically connecting the two printed circuit boards of a hearing aid. The electric connector does not require any fixing elements. The method comprises the manufacture of a so-called soldering comb. For that, at first there is provided a sheet-metal strip from which parallel conductor strips have been machined by etching or punching. The conductor strips are interconnected at their two ends each by cross lands. In a central region relative to the longitudinal direction of the conductor strips an insulating material is applied to both sides of the soldering comb to form the insulation zone. Here, the conductor strips at their ends and the two cross lands are exposed. After the cross lands have been removed the thus obtained soldering comb can be used to connect the two printed circuit boards. For that, the printed circuit boards—and thus, their terminals (in DE 38 42 572 A1 referred to as contact surfaces)—lie in one plane (see there FIG. 4). After having been connected the two printed circuit boards are folded parallel to each other. Here, the conductor strips at both exposed ends each have to be curved, i.e. bent. This is associated with a high stress of the conductor strips. There is not provided a bend within the insulation zone.

In the manufacture of a soldering comb it has to be noted that the material selection for the sheet-metal strips used influences the manufacturing method which is to be used. For punching a relatively hard material is needed. Soft materials cannot be punched. However, a soft material could be bent more easily.

It is the object of the invention to eliminate the drawbacks of the prior art. More particularly, there is provided an electric connector that withstands high bending stresses.

This problem is solved by the features of claim 1. Suitable developments of the inventions result from the features of the sub-claims.

According to the invention there is provided an electric connector that is particularly suitable for connecting printed circuit boards. The connector has several flat conductors that are spaced apart from each other and that are embedded in an electrically insulating material to form an insulation zone in which the flat conductors extend parallel to each other and at their ends each with an exposed portion project over the transverse edges of the insulation zone. Each flat conductor, within the insulation zone, has at least one first portion arranged between two second portions, wherein the first portion has a smaller thickness than the second portions.

In the meaning of the present invention a first portion of a flat conductor is between two second portions of the flat conductor in a state where the first portion with one end abuts on one end of a second portion and with its other end abuts on one end of the other second portion. The first portion should abut on a transverse edge of the insulation zone. Rather, second portions of the flat conductor may abut on both transverse edges of the insulation zone.

The flat conductors may have several first portions within the insulation zone. Since the first portions have a smaller thickness than the second portions the flat conductors on the first portions are weakened. Said weakening allows the electric connector to bend more easily. In contrast to the prior art the electric connector according to the invention allows bending of the flat conductor within the insulation zone.

Preferably, each flat conductor has several first portions, preferably three first portions or more. In this way the stress of the flat conductor by bending is distributed among several regions which prevents kinking of the flat conductor in one of the first regions. Such a kinking may occur if only a first portion having a too small thickness is provided. For this reason it is preferred that the thickness of the first portions is at least 25% of the thickness of one of the second portions. It is also preferred that the thickness of the first portions is at most 95% or less of the thickness of the second portions. In a preferred embodiment the thickness of the first portions is between 30 and 70% of the thickness of the second portions, more preferred between 45 and 55% and particularly preferred 50%.

The term “flat conductor” refers to a conductor substantially having a rectangular cross-section with the height of the conductor being smaller than the width of the conductor. The edges of the conductor may be rounded. The height of the second portions may be for example 0.2 mm or less, preferably 0.1 mm or less; the width of the first and second portions may be for example 0.5 to 2 mm.

To ease bending of the flat conductor within the insulation zone the first portion or, if several first portions are provided, one of the first portions relative to the longitudinal direction of the flat conductor is formed centrally within the insulation zone. If several first portions are provided, so it is preferred that in case the number of first portions corresponds to an odd number the middle one of the first portions is the centrally formed first portion relative to the longitudinal direction of the flat conductor.

Preferably, the weakening of the flat conductors by the first portions is only formed on one surface side of the flat conductors. In this case the first and second portions of the flat conductor have a common first surface side, whereas the second surface sides of the first portion are formed offset to the second surface side of the second portions. Forming the weakening such is suitable in case the flat conductors of the electric connector are only bent in one direction, namely in the direction in which the weakening is formed. A common surface side is meant to be a surface side in which no offset is formed between the first and second portions.

Alternatively, it may be provided that the weakening of the flat conductors by the first portions is only formed on both surface sides of the flat conductors. Here, in a first variant it may be provided that the first surface sides of the first portions are arranged offset to the first surface sides of the second portions and the second surface sides of the first portions are arranged offset to the second surface sides of the second portions.

In a second variant it may be provided that if several first portions are provided alternating to a first portion the first surface side of which is formed offset to the first surface sides of the second portions and the second surface side of which is not formed offset to the second surface sides of the second portions there follows a first portion the second surface side of which is formed offset to the second surface sides of the second portions and the first surface side of which is not formed offset to the first surface sides of the second portions.

Preferably, the flat conductors have the same width within the insulation zone, i.e. the first portions and the second portions only differ in their thickness, but not in their width. If several first portions are provided, so the first portions may have the same length. However, alternatively the first portions may also be of different lengths. So, the flat conductor may have at least one first portion of a first length and at least one first portion of a second length with the first length being longer than the second length. For example, it may be provided that the centrally formed first portion is longer than the remaining first portions. The remaining first portions each may be of the same length.

The thickness of the exposed portions of the flat conductors should correspond to the thickness of the second portions of the flat conductors within the insulation zone. The exposed portions form the contacts for contacting the electric or electronic components to be connected. The exposed portions may be deformed, for example may be formed curved, bent, or z-shaped.

Preferably, all of the flat conductors at least within the insulation zone have the same structure. Here, the first and second portions of the flat conductors should be formed in alignment to each other.

It may be provided that second portions of the flat conductor abut on both transverse edges of the insulation zone. Alternatively, it may be provided that each of the flat conductors, within the insulation zone, has a first region that lies between two second regions, wherein
in the first region first and second portions are formed,
the first portions are only formed in the first region,
the second regions abut on the transverse edges of the insulation zone, and
the thickness of the flat conductors in the second regions corresponds to the thickness of the second portions of the flat conductors in the first region.

Preferably, the first region and the second regions each are of the same length.

The flat conductors of the connector according to the invention may be copper conductors, aluminum conductors, or conductors made of another material conducting electric current. Preferably, the flat conductors are copper conductors. The flat conductors should be made of a solderable material. The flat conductors may have a surface finishing, for example a coating of silver, gold, tin, or palladium. The coating may be formed on the entire flat conductor or only on exposed portions of the flat conductor.

The flat conductors, within the insulation zone, extend in parallel to each other. Preferably, the conductors are equally spaced from each other to form a grid. The distance between adjacent flat conductors relative to the longitudinal axes of the flat conductors should be between 0.3 mm and 5 mm, preferably 0.5 and 2 mm, with a distance of 0.93 mm being preferred. The electric connector according to the invention should have at least two flat conductors. Preferably, the electric connector according to the invention has no more than sixty flat conductors.

For the preparation of the flat conductors known methods such as punching, etching, rolling, stamping, and milling may be used. Preferably, the conductor paths are formed by etching or punching taking a sheet-metal strip as a basis. Here, etching is particularly preferred. For example, the first portions may be prepared by using rollers in the circumferential surfaces of which notches are formed.

Preferably, the insulation zone comprises a first film and a second film between which the flat conductors are arranged. Here, the two films should be opposite to each other. For fixing the films on one another and on the surface sides of the flat conductors an adhesive agent may be provided. Especially, there may be applied adhesive layers to the inner surfaces of the films. Preferably, the films are plastic films. The plastic films for example may be made of polyethylene, polytetrafluoroethylene, polyamide, polyurethane, or another electrically insulation plastic.

Preferably, the insulation zone substantially has a rectangular cross-section. The longitudinal and/or transverse edges of the insulation zone may be rounded. The flat sides of the insulation zone do not have to be perfectly planar, but complementary to the contours of the conductors, as far as these extend within the insulation zone. Here, the term “transverse edge” of the insulation zone is meant to be an edge of the insulation zone which is transverse to the longitudinal direction of the flat conductors.

The electric connector according to the invention has the advantage that it can be handled like a rigid component, but its behavior is similar to that of a flexible component due to the simplified bending option. The electric connector according to the invention is suitable for automatic mounting, for example by means of the reflow soldering.

According to the invention there is further provided the use of an electric connector according to the invention for electrically connecting printed circuit boards. The terminals of the two printed circuit boards do not have to lie in one plane. The electric connector according to the invention may further be used for connecting electric and electronic components, in particular such components having printed circuit boards.

In the following the invention is explained in detail with the help of examples with respect to the drawings, wherein these examples are not intended to limit the invention. Here,

### BRIEF DESCRIPTION OF THE DRAWINGS

FIG. 1A shows a plan view of an electric connector according to the invention;

FIG. 1B shows a front view of an electric connector according to the invention;

FIG. 1C shows a side view of an electric connector according to the invention;

FIG. 2 shows a perspective representation of a machined sheet-metal strip for the preparation of a first embodiment of an electric connector according to the invention;

FIG. 3 shows a partial side view of a flat conductor made of the sheet-metal strip shown in FIG. 2;

FIG. 4 shows a perspective representation of a machined sheet-metal strip for the preparation of a second embodiment of an electric connector according to the invention;

FIG. 5 shows a partial side view of a flat conductor made of the sheet-metal strip shown in FIG. 4;

FIG. 6 shows a perspective representation of a machined sheet-metal strip for the preparation of a third embodiment of an electric connector according to the invention;

FIG. 7 shows a partial side view of a flat conductor made of the sheet-metal strip shown in FIG. 6; and

FIG. 8A shows a side view of an electric connector according to the invention having the flat conductors of FIGS. 6 and 7;

FIG. 8B shows a magnification of the circled portion of FIG. 8A showing an electric connector according to the invention having the flat conductors of FIGS. 6 and 7;

FIG. 9A shows a side view of the electric connector according to the invention shown in FIG. 8 that connects two printed circuit boards;

FIG. 9B shows a plan view of the electric connector according to the invention shown in FIG. 8 that connects two printed circuit boards;

FIG. 10A shows a side view of the electric connector according to the invention shown in FIG. 8 that connects two printed circuit boards;

FIG. 10B shows a perspective representation of the electric connector according to the invention shown in FIG. 8 that connects two printed circuit boards;

FIG. 11A shows a side view of the electric connector according to the invention shown in FIG. 8 that connects two printed circuit boards;

FIG. 11B shows a perspective representation of the electric connector according to the invention shown in FIG. 8 that connects two printed circuit boards;

FIG. 12A shows a side view of the electric connector according to the invention shown in FIG. 8 that connects two printed circuit boards;

FIG. 12B shows a perspective representation of the electric connector according to the invention shown in FIG. 8 that connects two printed circuit boards;

FIG. 13A shows a side view of the electric connector according to the invention shown in FIG. 8 that connects two printed circuit boards; and

FIG. 13B shows a perspective representation of the electric connector according to the invention shown in FIG. 8 that connects two printed circuit boards.

### DETAILED DESCRIPTION OF THE DRAWINGS

In the following drawings same reference numbers have the same meaning unless explicitly stated otherwise.

The first embodiment of an electric connector 1 according to the invention shown in FIGS. a-c has several parallel flat conductors 2 that are spaced apart from each other.

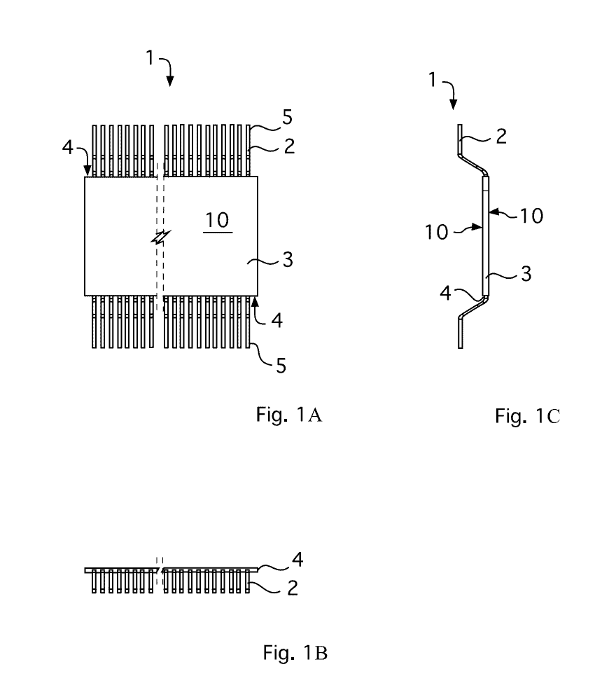

The flat conductors 2 are embedded in an electrically insulating material, whereby an insulation zone 3 is obtained. The insulation zone 3 is obtained by sandwiching the flat conductors 2 between two plastic films 10. The flat conductors 2 come out of the insulation zone 3 at its transverse edges 4. Outside the insulation zone 3 the conductors 2 have exposed portions 5. In FIG. 1c it can be seen that the exposed portions 5 of the flat conductors 2 are curved z-shaped. Leaving aside the contours of the flat conductors 2 the insulation zone 3 is flat.

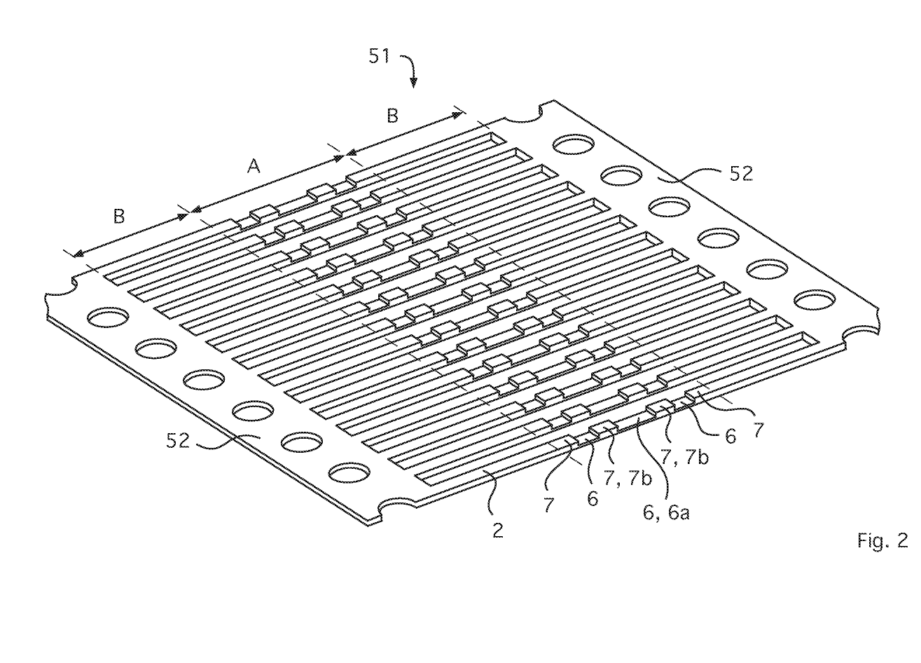

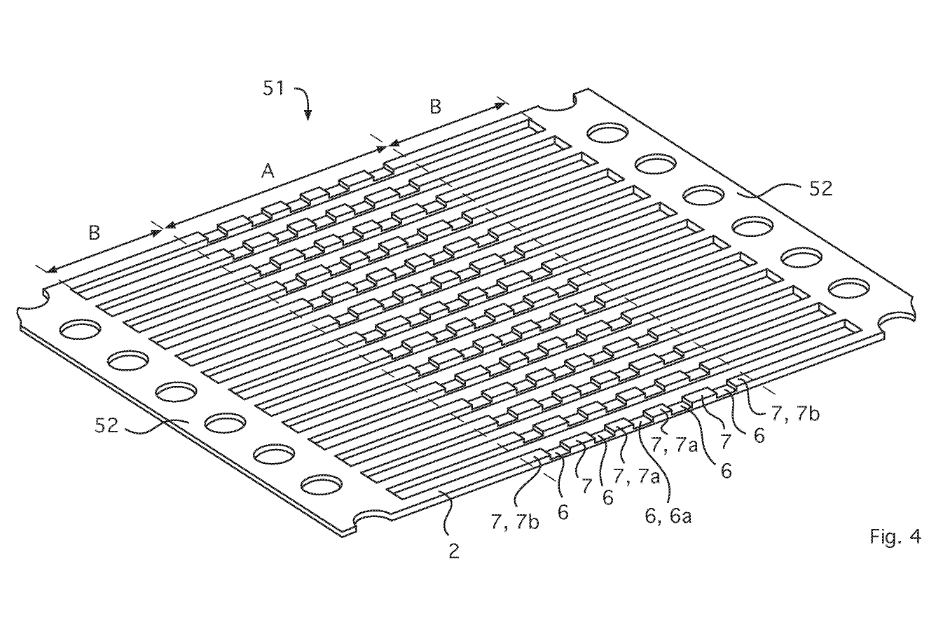

The flat conductors 2, within the insulation zone 3, each have at least one first portion 6 that lies between two second portions 7 (see, FIGS. 2 to 7). The first portions 6 of the flat conductors have a thickness of 50% of the thickness of the second portions 7.

FIGS. 2 to 7 show sheet-metal strips 51 that can be used to prepare embodiments of the electric connector according to the invention. From the sheet-metal strip 51 the flat conductors 2 are machined, for example by punching or etching. In the case of punching such sheet-metal strips 51 are also referred to as blanking skeletons. The flat conductors 2 are connected to each other in the sheet-metal strip 51 by lands 52. The flat conductors 2 are obtained from the sheet-metal strips 51 by separating the lands 52.

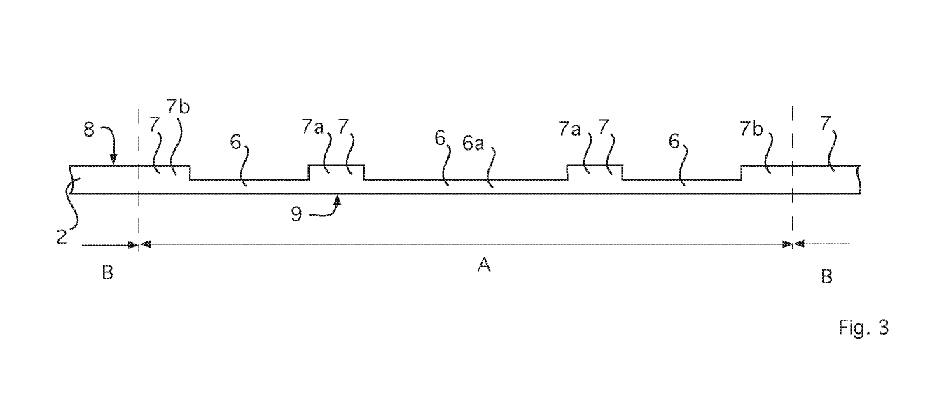

The flat conductors 2 of the sheet-metal strips 51 each have a first region A lying between two second regions B of the same length (see, FIGS. 2, 4, and 6). The first region A and adjacent portions of the second region of a flat conductor 2 are shown in figures 3, 5, and 7. The first region A shown in FIG. 3 has three first portions 6. The middle first portion 6a of the three first portions 6, i.e. the first portion 6a, that lies between the two other first portions 6 is centrally arranged relative to the length of the flat conductor 2. The middle first portion 6a has a length that is 1.5 fold the length of the two other portions 6 that both are of the same length. The three first portions 6 have a thickness that is 50% of the thickness of the second portions 7. The thickness of the second portions 7 corresponds to the thickness of the flat conductor 2 in the second regions B. An offset between the first portions 6 and the second portions 7 is only formed on one surface side 8 of the flat conductor 2. On the other surface side 9 of the flat conductor 2 there is no offset between the first portions 6 and the second portions 7. The two second portions 7a abutting on the central first portion 6a are of the same length that is half the length of the central first portion 6a. The two second portions 7b forming the transition between the first region A and the adjacent second regions B are of the same length, but are significantly longer than the second portions 7a.

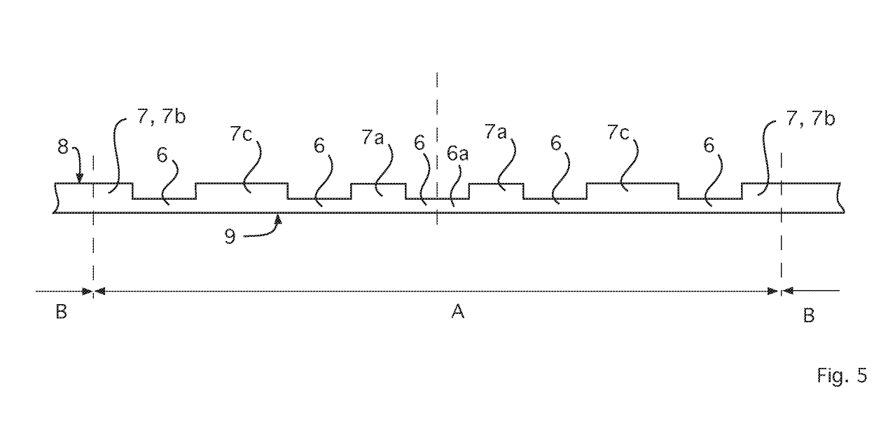

The first region A shown in FIG. 5 has five first portions 6. The middle first portion 6a of the five first portions 6 is centrally arranged relative to the length of the flat conductor 2. The first portions 6 all are of the same length. The five first portions 6 have a thickness that is 50% of the thickness of the second portions 7. The thickness of the second portions 7 corresponds to the thickness of the flat conductor 2 in the second regions B. An offset between the first portions 6 and the second portions 7 is only formed on one surface side 8 of the flat conductor 2. On the other surface side 9 of the flat conductor 2 there is no offset between the first portions 6 and the second portions 7. The two second portions 7a abutting on the central first portion 6a are of the same length. It is 80% of the length of the first portions 6. Both second portions 7b forming the transition between the first region A and the adjacent second regions B are of the same length, but are significantly longer than the second portions 7a and 7c lying between the outer first portions 6. The second portions 7c each are of the same length. It is 120% of the length of the first portions 6.

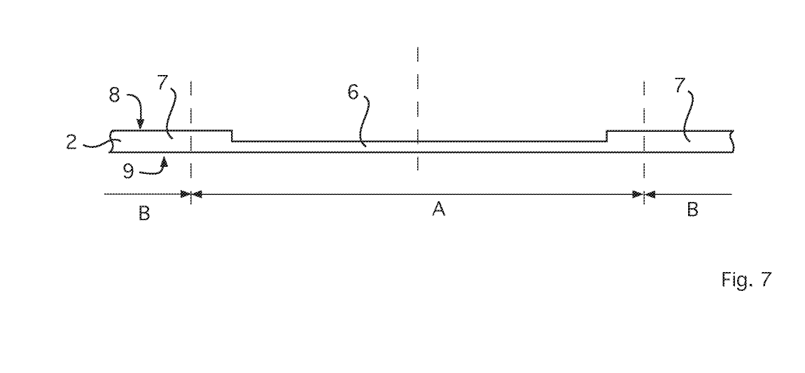

The first region A shown in FIG. 7 exactly has one first portion 6. Said first portion 6 is centrally arranged relative to the length of the flat conductor 2. The first portion 6 has a thickness that is 50% of the thickness of the second portions 7. The thickness of the second portions 7 corresponds to the thickness of the flat conductor 2 in the second regions B. An offset between the first portion 6 and the second portions 7 is only formed on one surface side 8 of the flat conductor 2. On the other surface side 9 of the flat conductor 2 there is no offset between the first portion 6 and the second portions 7. Both second portions 7 abutting on the first portion 6 are of the same length.

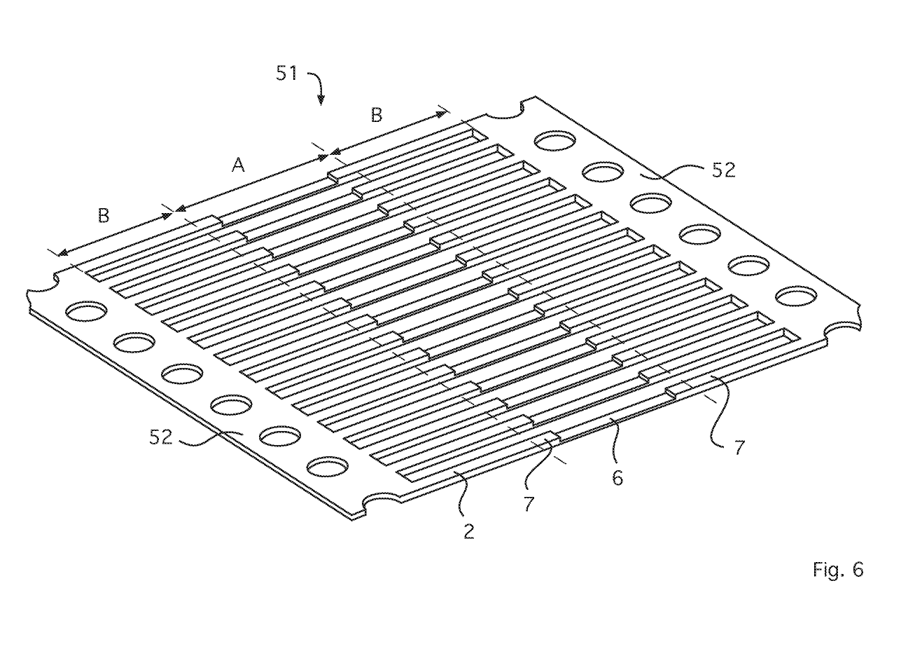

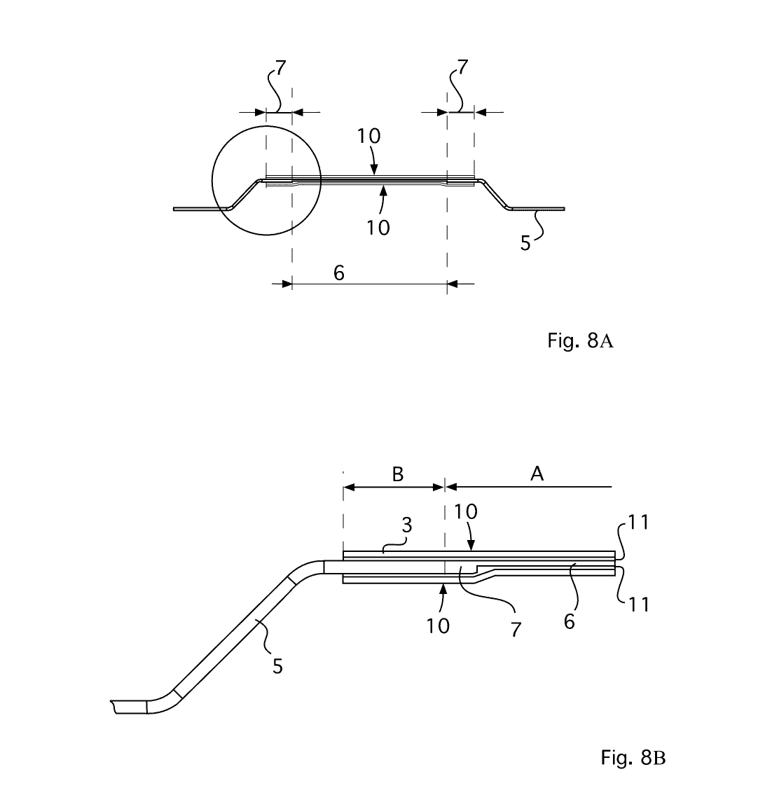

In FIGS. 8a and 8b there is shown a second embodiment of an electric connector 1 according to the invention that corresponds to the first embodiment shown in FIGS. 1a-c, except that the flat conductors 2 in the insulation zone 3 are derived from the sheet-metal strips 51 shown in FIG. 6. Thus, the flat conductors 2 of the second embodiment have only one first portion 6 that lies between two second portions 7. It is apparent from FIG. 8b that one of the plastic films 10 covers the offset formed on the surface side 8 between the first portion 6 and the second portions 7. The plastic films 10 each are coated with an adhesive layer 11 on the surface sides facing each other.

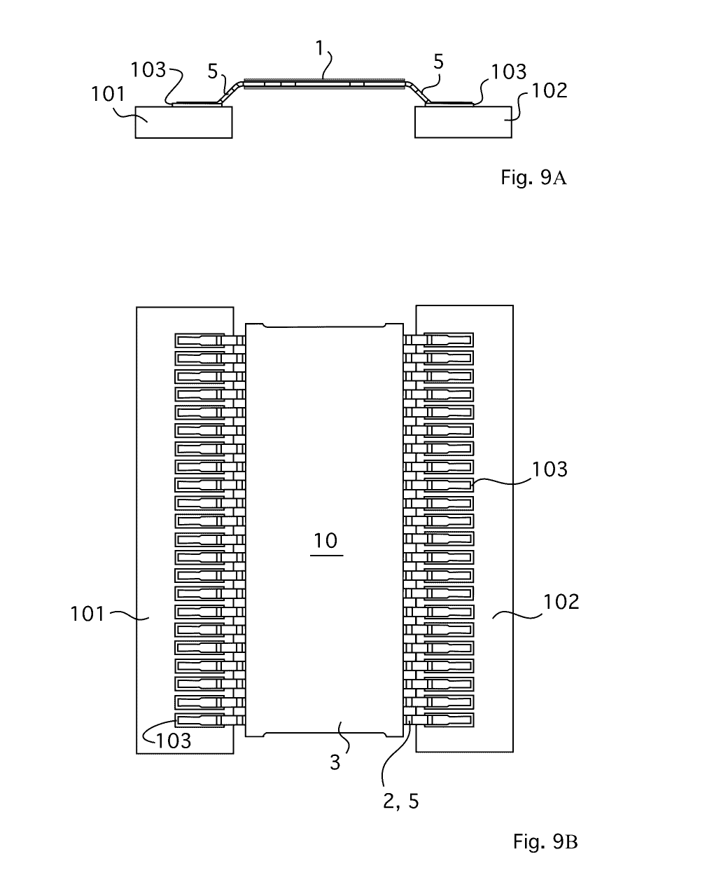

FIGS. 9 to 13 show the electric connector 1 illustrated in FIG. 8 in the mounted state in which it electrically connects two printed circuit boards 101, 102. Here, the exposed portions 5 of the flat conductor 2 are soldered up with contact surfaces 103 formed on the printed circuit boards 101, 102. Surface side 8 of the flat conductors 2 in which an offset is formed between the first and the second portions 6, 7 is on the side of the electric connector that faces the printed circuit boards 101, 102. The side of a printed circuit board 101, 102 on which the contact surfaces 103 are formed in the following are referred to as contact side. The contours of the flat conductors 2 within the insulation zone are indicated by broken lines.

In FIG. 9 the contact sides of the two printed circuit boards 101, 102 are in the same plane (with respect to the illustration this is the upper surface of the printed circuit boards). The flat conductors 2 of the electric connector 1 are not curved within the insulation zone 3.

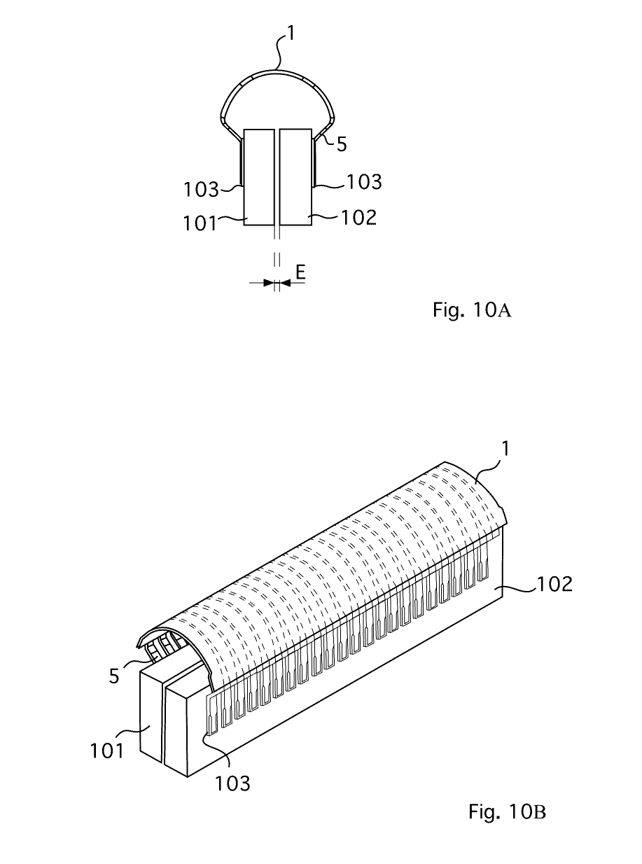

In FIG. 10 the contact sides of both printed circuit boards 101, 102 face away from each other. The distance E between both printed circuit boards 101, 102 is extremely low. The flat conductors 2 of the electric connector 1 are strongly curved within the insulation zone 3. After the electric connector 1 has been mounted on the printed circuit boards 101, 102 the flat conductors 2 were strongly bent within the insulation zone 3.

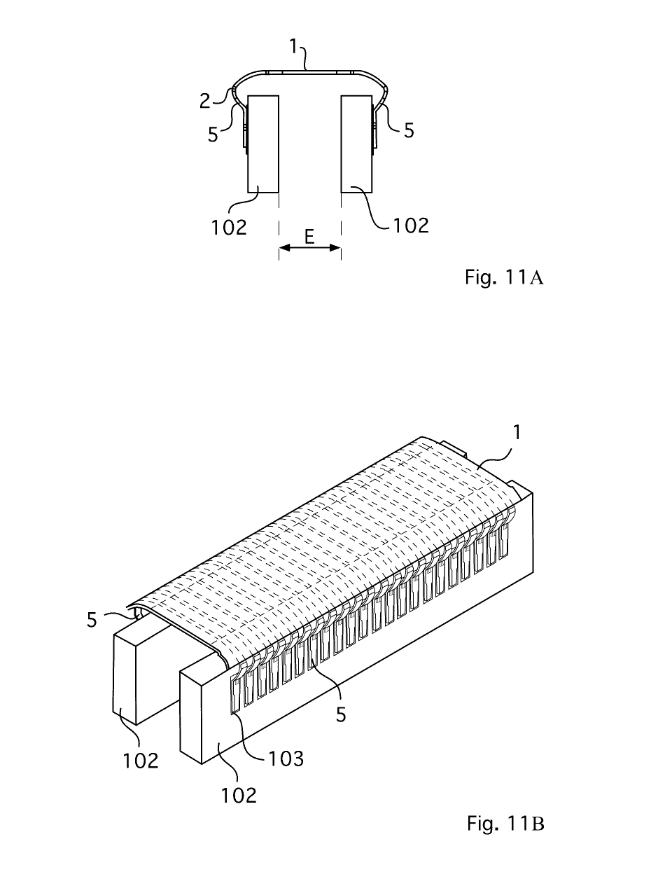

In FIG. 11 the contact sides of both printed circuit boards 101, 102 face away from each other. The distance E between both printed circuit boards 101, 102 is greater than in FIG. 10. The flat conductors 2 of the electric connector 1, within the insulation zone 3, are less curved than in FIG. 10. After the electric connector 1 has been mounted on the printed circuit boards 101, 102 the flat conductors 2 were bent within the insulation zone 3.

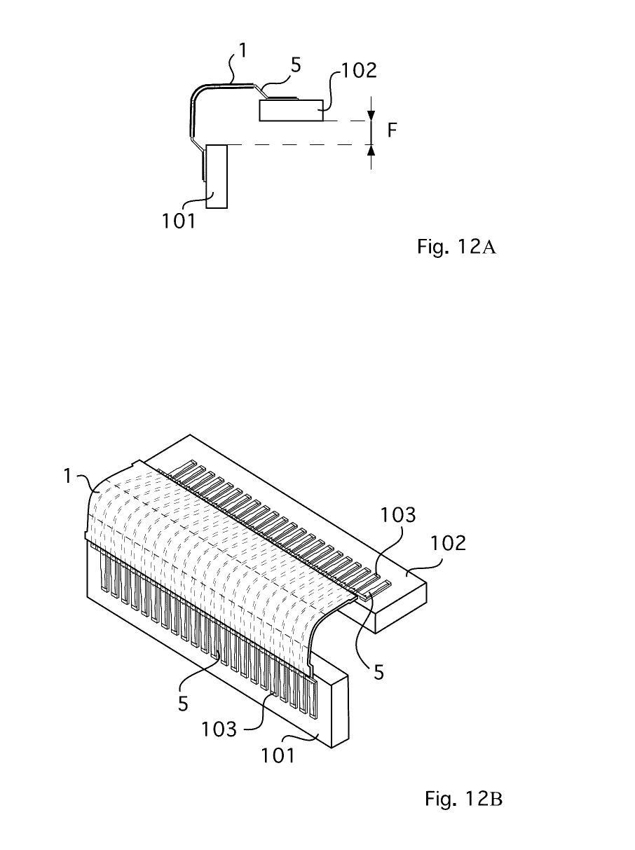

In FIG. 12 the contact side of printed circuit board 101 is orthogonally offset to the contact side of printed circuit board 102, wherein the contact sides of printed circuit boards 101, 102 each are formed on the side of printed circuit boards 101, 102 that faces away from the other printed circuit board. The distance E between the two printed circuit boards 101, 102 is small. The flat conductors 2 of the electric connector 1 are strongly curved within the insulation zone 3. After the electric connector 1 has been mounted on the printed circuit boards 101, 102 the flat conductors 2 were strongly bent within the insulation zone 3.

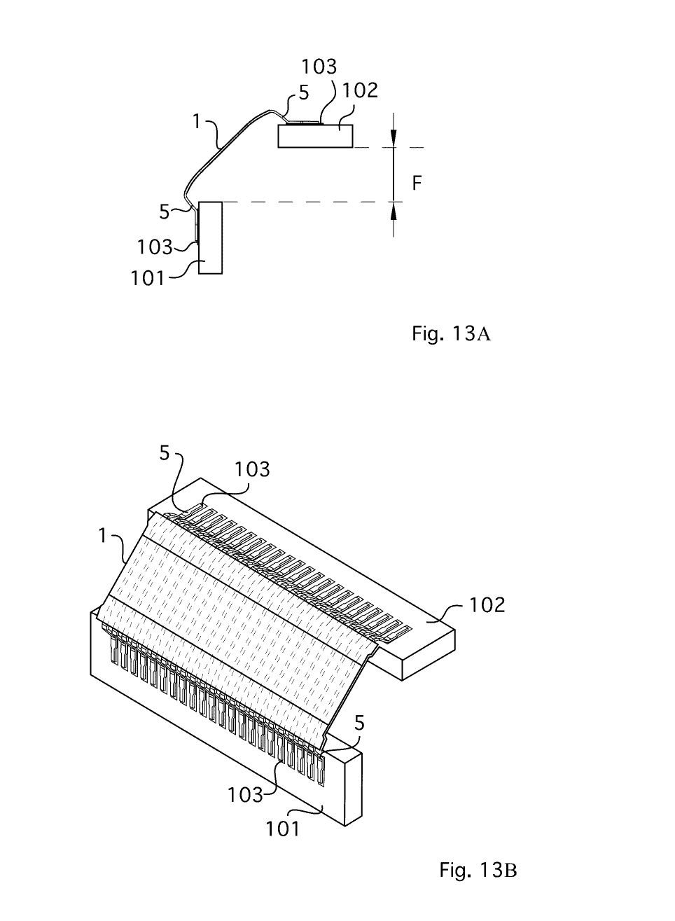

In FIG. 13 the contact side of printed circuit board 101 is orthogonally offset to the contact side of printed circuit board 102, wherein the contact sides of printed circuit boards 101, 102 each are formed on the side of printed circuit boards 101, 102 that faces away from the other printed circuit board. The distance E between the two printed circuit boards 101, 102 is greater than in FIG. 12. The flat conductors 2 of the electric connector 1, within the insulation zone 3, are less curved than in FIG. 12. After the electric connector 1 has been mounted on the printed circuit boards 101, 102 the flat conductors 2 were bent within the insulation zone 3.

### LIST OF REFERENCE NUMBERS

1 electric connector
2 flat conductor
3 insulation zone
4 transverse edge
5 exposed portion
6 first portion
7 second portion
8 surface side
9 surface side
10 plastic film
11 adhesive layer
A first region
B second region
E distance
51 sheet-metal strip
52 land
101 printed circuit board
102 printed circuit board
103 contact surface

1. An electric connector comprising:
wherein the connector has several flat conductors that are spaced apart from each other and that are embedded in an electrically insulating material to form an insulation zone in which the flat conductors extend parallel to each other and at their ends each with an exposed portion project over the transverse edges of the insulation zone, wherein each of the flat conductors, within the insulation zone, has at least one first portion that is arranged between two second portions, wherein the first portion has a smaller thickness than the second portions.

2. The electric connector according to claim 1, wherein the first portion relative to the longitudinal direction of the flat conductor is formed centrally within the insulation zone.

3. The electric connector according to claim 1, wherein the first and second portions have a common first surface side, whereas the second surface side of the first portion is formed offset to the second surface side of the second portions.

4. The electric connector according to claim 1, wherein the first surface side of the first portion is arranged offset to the first surface sides of the second portions and the second surface side of the first portion is arranged offset to the second surface side of the second portions.

5. The electric connector according to claim 1, wherein the flat conductor has several first portions that each are arranged between two second portions.

6. The electric connector according to claim 5, wherein the flat conductor has at least three first portions.

7. The electric connector according to claim 5, wherein the flat conductor has at least one first portion of a first length and at least one first portion of a second length with the first length being longer than the second length.

8. The electric connector according to claim 5, wherein the flat conductor has at least one second portion of a first length and at least one second portion of a second length with the first length being longer than the second length.

9. The electric connector according to claim 5, wherein second portions of the flat conductor abut on both transverse edges of the insulation zone.

10. The electric connector according to claim 1, wherein all of the flat conductors have the same structure and the first and second portions of the flat conductors are formed in alignment to each other.

11. The electric connector according to claim 1, wherein each of the flat conductors, within the insulation zone, has a first region lying between two second regions, wherein first and second portions are formed in the first region, the first portions are only formed in the first region, the second regions abut on the transverse edges of the insulation zone, and the thickness of the flat conductors in the second regions corresponds to the thickness of the second portions of the flat conductors in the first region.

12. The electric connector according to claim 11, wherein the first region and the second regions each are of the same length.

13. The electric connector according to claim 1, wherein the thickness of a first portion is 95% or less of the thickness of a second portion.

14. The electric connector according to claim 1, wherein the thickness of a first portion is 25% or more of the thickness of a second portion.

15. The electric connector according to claim 1, wherein the insulation zone comprises a first film and a second film between which the flat conductors are arranged, wherein an adhesive agent is provided for fixing the films.
